(19) United States
(12) Patent Application Publication
(10) Pub. No.: US 2022/0171900 A1
(43) Pub. Date: Jun. 2, 2022

(54) METHOD AND DEVICE FOR GENERATING A DATA INTEGRATION DEVICE

(71) Applicant: Robert Bosch GmbH, Stuttgart (DE)

(72) Inventors: Andreas Textor, Weinstadt-Beutelsbach (DE); Steffen Stadtmueller, Stuttgart (DE)

(21) Appl. No.: 17/456,944

(22) Filed: Nov. 30, 2021

(30) Foreign Application Priority Data
Dec. 2, 2020 (DE) 10 2020 215 232.2

(51) Int. Cl. G06F 30/20

(52) U.S. Cl. CPC G06F 30/20

(57) ABSTRACT

A data integration device, including input interfaces to which a device which delivers runtime data to the input interface is connectable in each case. The runtime data of the particular device are characterized with the aid of at least one aspect model that is associated with the particular input interface and that characterizes in each case an aspect of the runtime data. The particular input interface is associated with the particular aspect model.

### FIELD

The present invention relates to a method for generating a data integration device, a computer program, a machine-readable memory medium, and a computer.

### BACKGROUND INFORMATION

A method for generating a digital twin of a physical object is described in German Patent Application No. DE 10 2018 205 872 A1, in which description data containing properties of digital data are generated based on a description metamodel. In addition, communication information is created. The description data, the communication information, and a description of the physical object are combined to generate the digital twin.

### SUMMARY

The present invention may have the advantage over the related art that it provides a data integration device that is flexibly coupleable to a plurality of (runtime) data, it being ensured that the various specific properties of the particular (runtime) data may be taken into account in the interpretation in order to ensure a correct interpretation of the particular (runtime) data.

Further aspects of the present invention are disclosed herein. Advantageous refinements of the present invention are disclosed herein.

Specific embodiments of the present invention are explained in greater detail below with reference to the figures.

### BRIEF DESCRIPTION OF THE DRAWINGS

FIG. 1 shows an example of a use of the present invention.

FIG. 2 schematically shows data flows through the data integration device, in accordance with an example embodiment of the present invention.

FIG. 3 schematically shows a mechanism for coupling a data-transmitting device, in accordance with an example embodiment of the present invention.

FIG. 4 shows in a flowchart an example of a method for providing a digital twin, in accordance with an example embodiment of the present invention.

FIG. 5 shows an example of data of a blast furnace provided by an aspect agent, in accordance with an example embodiment of the present invention.

FIG. 6 shows an example of an aspect model for this aspect agent, in accordance with an example embodiment of the present invention.

FIG. 7 shows an example of a class hierarchy for establishing properties of subgraphs of the aspect model, in accordance with an example embodiment of the present invention.

### DETAILED DESCRIPTION OF EXAMPLE EMBODIMENTS

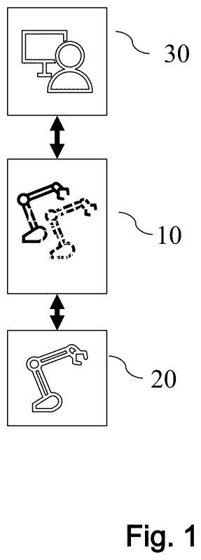

FIG. 1 shows an example of a use of the present invention. A data integration device 10 is provided for being coupled to devices 20 and client-side devices 30. Device 20 may be, for example, a sensor and/or an ERP system and/or a production machine such as a blast furnace and/or a robot, for example a welding robot, and/or a vehicle and/or a charging station, for example for an electric vehicle. Coupled devices 20 are configured to transfer information to data integration device 10.

Client-side devices 30 may be, for example, reproducing devices or also devices that access devices 20 for control of same.

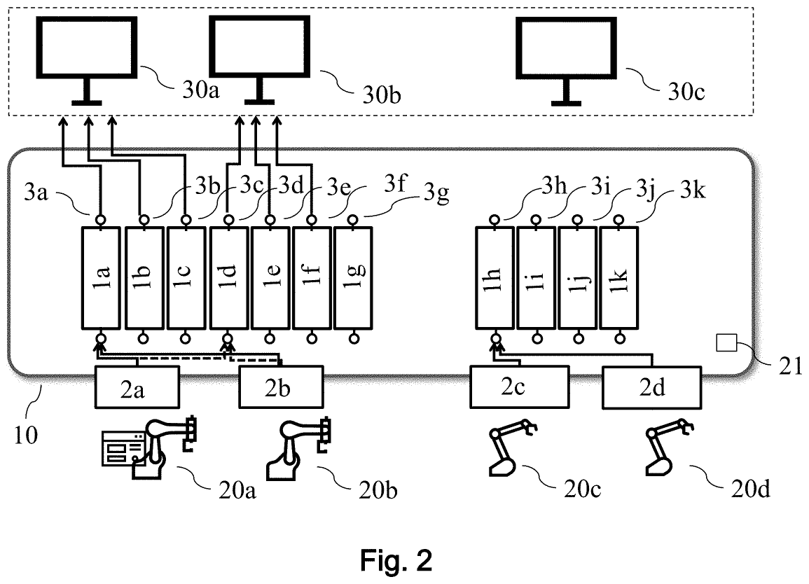

FIG. 2 shows, in one exemplary embodiment, how the data flows through data integration device 10 take place. Devices 20a . . . d are coupled to data integration device 10 via a respective input interface 2a . . . 2d. Each of data integration devices 10 is connected to one or multiple aspect agents 1a . . . k (also referred to as aspect processing devices), it being possible for different coupled devices 20a . . . d to be connected, via their respective input interfaces 2a . . . d, to same aspect agents 1a . . . k. The aspect agents are referred to as first 1a, second 1b, third 1c, fourth 1d, fifth 1e, sixth 1f, seventh 1g, eighth 1h, ninth 1i, tenth 1j, and eleventh 1k aspect agent. Each aspect agent includes a respective output interface 3a . . . 3k, which with the same numbering as the aspect agents is referred to as first 3a, second 3b, third 3c, fourth 3d, fifth 3e, sixth 3f, seventh 3g, eighth 3h, ninth 3i, tenth 3j, and eleventh 3k output interface, first aspect agent 1a including first output interface 3a, the second aspect agent including the second output interface, etc.

In the illustrated exemplary embodiment, a first device 20a is coupled to first aspect agent la and to fourth aspect agent 1d via a first input interface 2a, and a second device 20b is likewise coupled via a second input interface 2b.

A third device 20c is coupled to ninth aspect agent 1h via a third input interface 2c. Likewise, a fourth device 20d is coupled via a fourth input interface 2d.

Input interfaces 2a . . . d are each configured to receive data of devices 20a . . . d, to which they are respectively connected, in a specific format for particular connected device 20a . . . d.

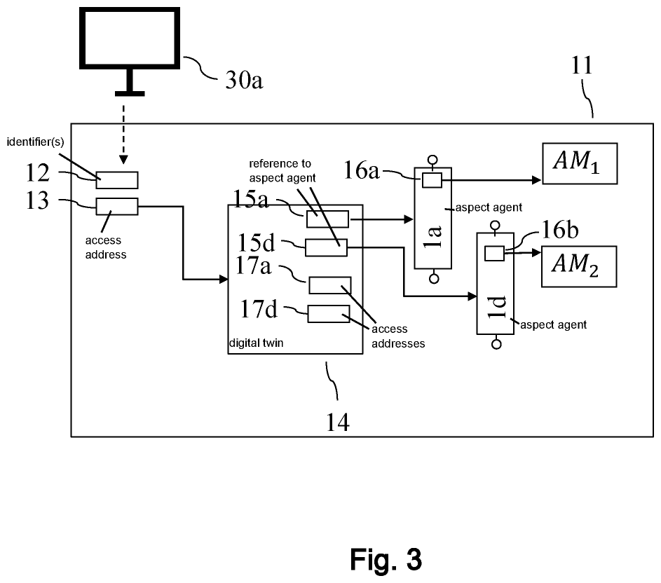

One or multiple (semantic) aspect models AM₁, AM₂ (cf. FIG. 3) are stored in a dedicated location in a memory 21, a so-called model repository, that is associated with data integration device 10. Data integration device 10 may access these aspect models AM₁, AM₂. For each aspect agent la . . . k, a reference to an aspect model AM₁, AM₂ that is associated with this particular aspect agent 1a . . . k is stored. Each of aspect models AM₁, AM₂ describes at least a portion of the properties of the data received from particular data-transmitting device 20a . . . 20d that is connected via one of input interfaces 2a . . . 2d.

Each of aspect models AM₁, AM₂ may be associated with a plurality of aspect agents 1a . . . 1k due to the storing in the model repository.

Each of aspect agents 1a . . . 1k is configured to receive data from respective connected data-transmitting device 20a . . . 20d and to provide at least a portion of the data to output interface 3a . . . 3k of the aspect agent.

Aspect models AM₁, AM₂ each describe, for example, the structure of at least a portion of the data provided by particular aspect agent 1a . . . k that references this aspect model M₁, AM₂, and/or properties of the data provided by this aspect agent 1a . . . k.

The properties of the described data include, for example, data types, possible or allowable value ranges, and/or a physical unit, which represent the particular data.

The particular data received from data-transmitting device 20a . . . d are provided to output interfaces 3a . . . k and are retrievable there. A reference to one or multiple corresponding aspect models AM₁, AM₂ is also associated with each output interface 3a . . . k. Those data of data-transmitting device 20a . . . d for which descriptions are present in respective associated aspect models AM₁, AM₂ are retrievable via output interface 3a . . . k.

Each aspect model AM₁, AM₂ thus describes a data structure via which associated output interface 3a . . . k allows access to the portions of the data defined by aspect model AM₁, AM₂ in each case, and provides descriptive information for this purpose.

First output interface 3a, second output interface 3b, and third output interface 3c are connected to a first terminal 30a, for example a monitor for displaying the data received via the connected output interfaces, or to a data processing device that further processes the received data, for example stores them in a database.

As a result of the data, to which output interface 3a . . . k provides access, being provided by associated aspect model AM₁, AM₂, homogeneous access to the data occurs, even though different devices 20a . . . d may be connected to input interface 2a . . . d.

FIG. 3 illustrates a mechanism for coupling a data-transmitting device, in the present case, the coupling of first device 20a. For the coupling, a digital twin 14 of first device 20a is applied (in particular, such a digital twin is provided for each coupled device) and provided under an access address 13. This takes place based on predefinable aspect agents 1a . . . 1k, as illustrated here in FIG. 2 by way of example, based on first aspect agent 1a and fourth aspect agent 1d.

For this purpose, one or multiple identifiers 12 of first device 20a to be coupled are stored in a registry 11, which may be stored in memory 21, for example, as well as access addresses 17a, 17d at which output interfaces 3a . . . 3k that are associated with aspect agent 1a . . . k may be accessed, and that are associated with the device to be coupled, in the present case, first device 20a. In the exemplary embodiment, access addresses 17a, 17b address first output interface 3a and fourth output interface 3b.

In addition, for each output interface 3a, 3d, i.e., each aspect agent 1a, 1d, a reference 16a, 16b to descriptive aspect model AM₂, AM₂ provided in the model repository is provided in registry 11.

The topology may of course differ. In particular, it is possible for a data structure, for example a table, that is filterable according to identifiers 12 to be stored in the registry.

If a terminal 30a is now to carry out an action, predefinable by the user, on first device 20a in the example, the data delivered by first device 20a via first input interface 2a are retrievable at first output interface 3a and fourth output interface 3d via access addresses 17a, 17b, in conjunction with stored aspect models AM₁, AM₂, which in each case describe a partial aspect of the delivered data.

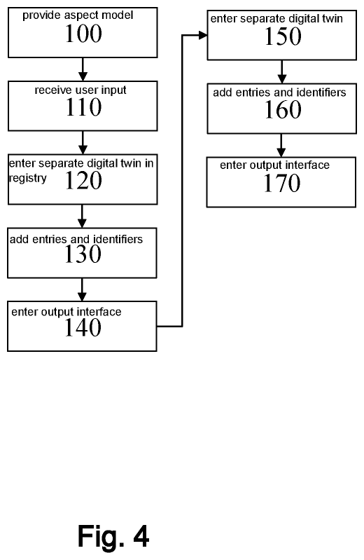

FIG. 4 illustrates in a flowchart an example of a method for providing a digital twin 14 together with aspect agents 1a . . . k and their use, using the example of a blast furnace and a welding robot as data-transmitting devices 20a . . . d to be coupled.

An aspect model AM₁, AM₂ for maintenance information is initially provided 100 in the model repository by a user, for example a maintenance engineer.

A user input that accesses this provided aspect model AM₁, AM₂ is then received 110. An aspect agent 1a . . . k is then generated, in particular automatedly, and is configured to receive data from the blast furnace, select maintenance data contained therein, optionally transform same, and provide the maintenance data to output interface 3a . . . k of the aspect agent.

The entry of a separate digital twin 14 into registry 11 subsequently takes place 120 for each blast furnace of this type to be connected.

In particular, an entry or multiple entries in the registry together with identifiers of the particular connected blast furnace may be added 130 to each digital twin. This allows the traceability of which devices 20a . . . d provide an aspect agent 1a . . . k with data.

In general, the digital twin may be a separately maintained data structure, but it is also possible for the digital twin to be embedded in a larger data structure. It is thus possible, for example, for the pieces of information that make up the digital twin to be aggregated in a list. Thus, the digital twin of a predefinable connected device may then be provided, for example by filtering the list according to the indicator of the predefinable connected device.

For each digital twin 14 in registry 11, an entry 140 of output interface 3a . . . k for particular aspect agent 1a . . . k, i.e., the maintenance aspect model in this case, subsequently takes place.

The blast furnace is coupled in this way.

A different user may likewise subsequently access this aspect model AM₁, AM₂, and may generate an aspect agent that collects data from a welding robot, appropriately selects maintenance data, transforms same, and provides the data to the output interface.

Initially a step 150 follows that is analogous to step 120.

Step 160 then follows, which is analogous to step 130.

Step 170 then follows, which is analogous to step 140.

In this example, a computer program that accesses this maintenance aspect model may now be provided for planning maintenance operations. This computer program may now be used for blast furnaces as well as for welding robots. This computer program may access registry 11 as described.

Particular aspect model AM₁, AM₂ follows the rules of a metamodel. In particular, aspect model AM₁, AM₂ is structurally a directed graph, in which nodes represent, describe, and identify individual data points (so-called properties) and groups of data points, which are provided to output interface 3a . . . k of an aspect agent 1a . . . k.

The structure of the directed graph (i.e., the links between the nodes of the data points and the data point groups) thus allows the unambiguous derivation of the structure of the (runtime) data that are provided to output interface 3a . . . k of aspect agent 1a . . . k.

In addition, an aspect model AM₁, AM₂ graph contains one or multiple subgraphs (so-called characteristics) that establish the properties (data type, value range, physical unit, etc.) of the represented data points, during traversal of the graph up to a predefinable data point at least one or multiple such characteristic subgraphs also being unambiguously reachable for the data point. This is important, since the (runtime) data provided by an aspect agent have the predefined properties and must be interpreted accordingly. It is thus possible to unambiguously ascertain and provide these properties during the traversal.

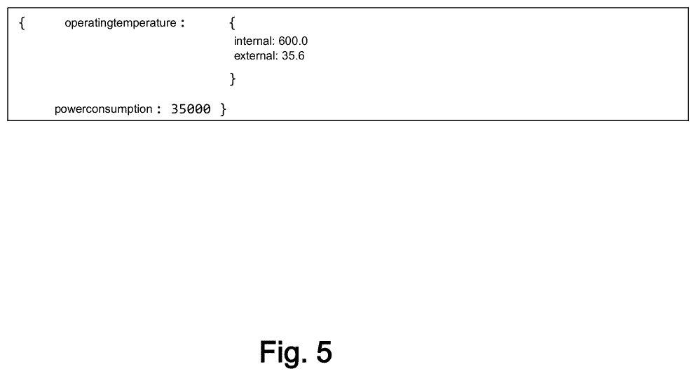

FIG. 5 illustrates an example of data of a blast furnace provided by an aspect agent 1a . . . k. These data include data concerning the internal and external operating temperatures and the present power consumption of the furnace.

Two data points with the identifiers “power consumption” and “operating temperature” are initially described. Whereas power consumption has a scalar value “35,000,” the value of “operating temperature” is a complex object which in turn contains two further data points: “internal” and “external” with the respective scalar values “600.0” and “35.6.”

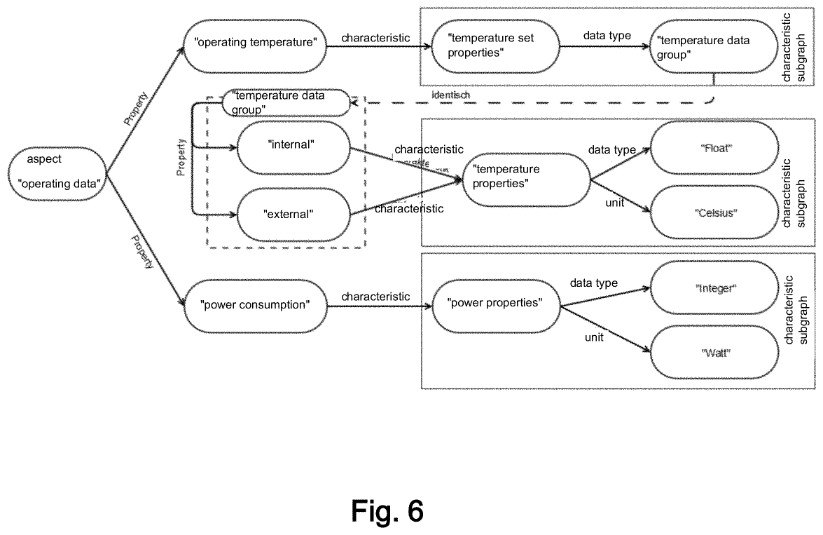

FIG. 6 shows an example of an aspect model for this aspect agent. The identifiers of the data points, i.e., “operating temperature” and “power consumption,” each point to a characteristic subgraph which establishes properties with regard to data type and, if possible, its physical unit. The complex data type for “operating temperature” is likewise defined in the aspect model. This takes place by providing the contained data points. The values of the data points are not present in the aspect model, since they are not provided until runtime, and may continuously change.

Lastly, it is also possible that accesses to runtime data may be predefined from terminal 30a . . . c at the output interface via so-called “operations,” or that access to information takes place via the runtime data, or that an access to functions takes place via which the connected device may be activated.

It is likewise possible to define an operation in the aspect model as a function that may be called up (for example, “turn on blast furnace” or “turn off blast furnace”). Such an operation may require input data, and may deliver output data. These data may likewise be described in the aspect models, the properties of the represented data points of the input/output data likewise being described using characteristic subgraphs. These input/output data may or may not be part of the data which are otherwise also retrievable.

For example, an “operating state aspect model” of the furnace contains the representation of a data point “status,” the characteristic subgraph describing two possible values as a value range: “on” or “off.” In addition, the operating state aspect model may indicate the operation “turn on,” whose output data likewise contain the representation of the data point “status.”

An aspect agent that follows an aspect model using operations must thus provide for the call-up of these operations at its “output interface” as an input interface for the information flow in the opposite direction.

The properties that may be established by the characteristic subgraphs within an aspect model in order to describe the data points represented in the aspect model are predefined by a metamodel. The properties that are usable for the description are subdivided into classes. These classes are predefined in a hierarchical structure for describing a represented data point of selectable classes.

In addition, establishing the possible properties for describing the data points in a class hierarchy allows the creation of aspect models in an editor, which allows the users to easily select the elements that are available for the description.

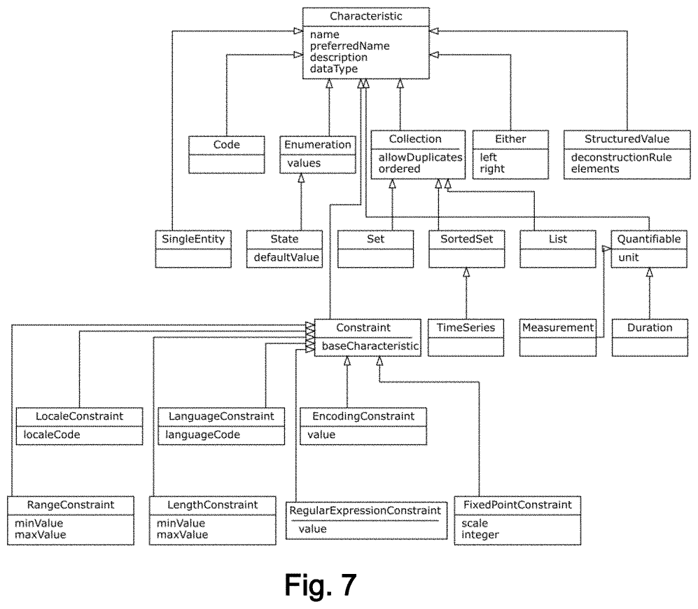

One example of such a class hierarchy is illustrated in FIG. 7, where “A→B” means that class A is a class that is derived from class B. It is important that the hierarchical configuration represents inheritance relationships in an “is a” relationship; i.e., descriptive properties that may be represented by class B in an aspect model may likewise be represented by class A, it being possible to additionally represent further properties in class A. The classes are thus expandable in a particularly simple manner.

The class hierarchy illustrated by way of example in FIG. 7 is used to establish, as an example, usable properties in characteristic subgraphs. By use of this example of a hierarchy, the characteristic subgraphs from the aspect model illustrated in FIG. 6 by way of example may be associated with the following classes:

The temp-set properties are from the single entity class, the temperature properties are from the measurement class, and the power properties are likewise from the measurement class.

The specific forms of the characteristic subgraphs are instances of the classes provided in the class hierarchy.

Predefining a hierarchical structure of classes in a metamodel with properties for the data point description is a prerequisite for using the aspect models that follow the metamodel.

For example, an aspect agent 1a . . . k may be created automatedly from existing aspect models.

Alternatively or additionally, evaluation functions (more precisely: a program code of this evaluation function) may be generated for the automated processing of data that are provided by aspect agents 1a . . . k at their respective output interface 3a . . . k.

Alternatively or additionally, the evaluation functions may be parameterized using aspect models.

Alternatively or additionally, descriptions in Interface Description Language (IDL) may be generated from provided aspect models. These descriptions may in turn be used to enable an application to consume the data that are provided by the particular aspect agent.

Alternatively or additionally, it is possible to generate semantic descriptions in ontology formats or logic formats, such as Web Ontology Language (OWL) or Common Logic (CL), from existing aspect models. It is thus possible to integrate the data provided by an aspect agent as well as the corresponding aspect models into a structured database such as a knowledge graph.

Alternatively or additionally, specialized or technical descriptions may be generated from provided aspect models, which in textual and graphical form describe the semantics of the aspect model in the particular domain, the description containing the structure of the data provided by aspect agent 1a . . . k at its output interface 3a . . . k, and in addition including the classification into the specialized context and the linkage to elements from particular standards and norms that are relevant in each case.

These types of fragments, i.e., evaluation functions or descriptions, may be generated from provided aspect models according to one of the methods described below.

One specific embodiment of the first such method provides that the graph of the aspect model is (preferably recursively) traversed. In addition, a mapping function is applied which generates a suitable subelement of the target format from the particular element of the aspect model, taking the associated semantics of the metamodel into account.

In the case of the evaluation function, the subelements are classes or functions, for example.

For example, for generating an application for monitoring operating data for blast furnaces, a mapping function may be defined during production, according to which all data points that are described by a characteristic subgraph, which is one instance of the measurement class, are mapped onto a predefinable class. In addition, the generated classes then automatically allow access to the unit of the data point having a predefined function, as illustrated by way of example in the following lines of pseudocode.
Property(Characteristic.class=Quantifiable)->Class<Property.name>
(Characteristic.class=Quantifiable). unit->Function: getUnit( )

By applying these mapping functions to aspect model 1 illustrated in conjunction with FIG. 6, using the class hierarchy illustrated by way of example in conjunction with FIG. 7, the following three program code classes may then be generated:
temperature.internal
temperature.external
power consumption

Since the measurement class corresponding to the hierarchy established in FIG. 8 by way of example is also a “quantifiable,” the data points “temperature.internal” and “temperature.external” may be recognized as relevant for the mapping condition.

Each of the generated program code classes allows access to the particular physical unit (degrees Celsius or watts) by calling up predefined function.getUnit( ).

The program code classes generated in this way allow display of the data, provided at output interface 3a . . . k of aspect agent 1a . . . k, which provides data corresponding to the aspect model, with an automatic, correct display of the physical unit of the represented values.

In addition, the same application may display other arbitrary data points (having a quantifiable characteristic) of other aspect agents by analogous automated generation of further program code classes for the corresponding aspect models.

A more specific use of the semantics of the elements in the aspect model is likewise possible, for example by configuration by the user of the application, which may establish, for example, that data points according to the “temperature properties” characteristic are to be represented in a predefinable graphical form, for example in the form of a thermometer, or data points of the “power properties” characteristic are to be represented by a level display.

One specific embodiment of a second method for generating the evaluation functions or descriptions provides, for each target format, for the provision of a set of patterns which may recognize subgraphs of an aspect model (with regard to structure and content); i.e., the one pattern checking function for all subgraphs of the aspect model checks whether they match (with regard to structure or content) the provided pattern, and in the event of a match this subgraph is provided as recognized.

A corresponding set of subelements of the target format is associated with each pattern. For the generation operation, all patterns for the particular target format are run through, each pattern is applied to the output aspect model, and the subgraph of the aspect model resulting from the pattern recognition is mapped onto the subsets of the target format. Lastly, all subsets are combined to obtain the result.

For example, for the automatic generation of an aspect agent that is to be coupled to a blast furnace, it may be provided that the access addresses of the output interfaces are generated, so that in addition to the complete retrieval of all data points described in the associated aspect model, an individual retrieval of the individual data points is also made possible by this data-consuming application.

For this purpose, paths of the access address are generated as follows: The generation encompasses the establishment of a pattern, application to the particular aspect model, and mapping onto path elements, as follows:

Each represented data point results in a path element having the name of the data point. If a represented data point is part of a data point group, the corresponding path element is the successor of that path element which is associated with this data point group.

This takes place within the characteristic subgraph that is predefined by the metamodel.

Application to the aspect model illustrated by way of example in conjunction with FIG. 6 results in the following paths for the output interface of the aspect agent:
/operating data/temperature/internal
/operating data/temperature/external
/operating data/power consumption

(In this regard, “/operating data” is assumed as the general access address for retrieving all data points described by the aspect model.)

In order for the two presented methods to be implementable, the hierarchical structure of the metamodel and following the rules of the metamodel by the particular aspect model are important. In addition, it is necessary to describe the semantics, going beyond the structure of the data, in the form of characteristics which as model elements are an inherent component of an aspect model. Mapping functions of aspect model elements or subgraphs of the aspect model for the particular target format must be able not only to reference the semantics of the particular model elements predefined by the metamodel, but also to evaluate the inheritance hierarchies of the referenced metamodel elements. This is necessary for generating program code for evaluation functions, in which the inheritance hierarchy may also be utilized in order to achieve, where necessary, analogous structures in generated classes. It is likewise necessary for generating other formats in which only the inheritance ensures the degree of decoupling of the generated structures, which is effectively necessary for utilizing same.

In addition, an information processing system may be provided in which terminal 30 holds a description ready that describes semantics of one of aspect models AM₁, AM₂, this description being generated with the aid of particular aspect model AM₁, AM₂.

It may be provided that the description contains a structure of the data provided by aspect processing device 1a . . . k to its output interface 3a . . . k.

Furthermore, an information processing system may be provided in which the generation includes traversing the graph of aspect model AM₁, AM₂.

It may be provided that the generation includes applying a mapping function, which generates a corresponding subelement of the evaluation function or description from an element of aspect model AM₁, AM₂, taking semantics of the metamodel into account.

It may be further provided that the corresponding subelement of the evaluation function is a class, or a function that may be called up.

Moreover, an information processing system may be provided in which the generation involves providing at least one pattern for identifying subgraphs of the graph of aspect model AM₁, AM₂.

In further aspects of the present invention, it may be provided that data integration device 10 encompasses that the portion provided to output interface 3a, . . . , 3k includes all runtime data that characterize that aspect model AM₁, AM₂ which is associated with aspect processing device 1a, . . . , 1k to which output interface 3a, . . . , 3k belongs.

Data integration device 10 may be configured to also provide metadata, describing the provided runtime data, to output interface 3s, . . . , 3k.

In addition, a data integration device 10 may be provided in which a plurality of input interfaces 2a, . . . , 2d are associated with same aspect model AM₁, AM₂.

Furthermore, a data integration device 10 may be provided in which a plurality of input interfaces 2a, . . . , 2d are connected to same aspect processing device 1a, . . . , 1k.

Moreover, a data integration device 10 may be provided in which a plurality of aspect models AM₁, AM₂ are associated with at least one input interface 2a, . . . , 2d.

In addition, a data integration device 10 may be provided in which at least one input interface 2a, . . . , 2d is connected to a plurality of aspect processing devices 1a, . . . , 1k.

Furthermore, a data integration device 10 may be provided in which aspect model AM₁, AM₂ includes a semantic description of the runtime data that are present at particular input interface 2a, . . . , 2d.

It may be provided that the semantic description includes a description of a data type of the runtime data.

It may also be provided that the semantic description includes a description of an allowable value range of values contained in the runtime data and/or a description of a physical unit of the parameter that is described by values contained in the runtime data.

In a further aspect, the present invention relates to an information processing system, including data integration device 10 and at least one connected device 20a, . . . , 20d.

It may be provided that connected device 20a, . . . , 20d is a sensor and/or an ERP system and/or a production machine and/or a robot and/or a vehicle and/or a charging station.

In addition, an information processing system including data integration device 10 may be provided, including a terminal 30a . . . c for processing data that are provided to output interface 3a . . . k to which terminal 30a . . . c is connected.

Furthermore, an information processing system including the data integration device may be provided, including an evaluation function for processing the data provided at output interface 3a . . . k, the evaluation function being generated using aspect model AM₁, AM₂ of aspect processing device 1a . . . k associated with output interface 3a . . . k.

Moreover, an information processing system may be provided, the evaluation function being parameterized using aspect model AM₁, AM₂ of aspect processing device 1a . . . k associated with output interface 3a . . . k.

In addition, an information processing system may be provided, terminal 30a . . . c being configured to use a description that is generated using an aspect model AM₁, AM₂.

It may be provided that the description includes a semantic description in an ontology format or logic format.

It may be provided that terminal 30a . . . c includes a knowledge graph, and terminal 30a . . . c being configured to integrate the data provided at an output interface 30a . . . c by associated aspect processing device 1a . . . k, as well as associated aspect models AM₁, AM₂, into the knowledge graph.

Furthermore, an information processing system may be provided in which terminal 30 holds a description ready that describes semantics of one of the aspect models AM₁, AM₂, this description being generated with the aid of particular aspect model AM₁, AM₂.

It may be provided that the description contains a structure of the data provided by aspect processing device 1a . . . k at its output interface 3a . . . k.

Moreover, an information processing system may be provided in which the generation includes traversing the graph of aspect model AM₁, AM₂.

It may be provided that the generation includes applying a mapping function, which generates a corresponding subelement of the evaluation function or description from an element of aspect model AM₁, AM₂, taking semantics of the metamodel into account.

It may be further provided that the corresponding subelement of the evaluation function is a class, or a function that may be called up.

In addition, an information processing system may be provided in which the generation involves providing at least one pattern for identifying subgraphs of the graph of aspect model AM₁, AM₂.

### LIST OF REFERENCE NUMERALS

1a . . . 1k aspect processing device, aspect agent

2a . . . 2d device

3a . . . 3k output interface

10 data integration device

11 registry

12 identifier (of the device to be coupled)

13 access address for digital twin

14 digital twin

15a, d reference to aspect agent

20 device

20a . . . d device

30 terminal

30a . . . c terminal

1-15. (canceled)

16. A method for generating a data integration device, including respective input interfaces to each of which a respective device, which delivers respective runtime data to the respective input interface, is connectable, the respective runtime data of each of the respective devices being characterized using at least one respective aspect model that is associated with the respective input interface and that characterizes an aspect of the respective runtime data, the method comprising:
providing, from a metamodel, to each respective input interface associated with the respective aspect model, respective rules that are defined by the metamodel; and
setting up each respective aspect model according to the respective rules.

17. The method as recited in claim 16, wherein a structure of each respective aspect model is a respective directed graph.

18. The method as recited in claim 17, wherein nodes identify individual data points and/or groups of data points in each respective directed graph.

19. The method as recited in claim 18, wherein the structure of each respective aspect model contains at least one respective subgraph that describes properties of the data points identified by the nodes and/or properties of the data points of the group identified by the nodes.

20. The method as recited in claim 19, wherein at least one respective subgraph is also unambiguously reachable during traversal of the graph up to a predefinable node.

21. The method as recited in claim 20, wherein the data integration device is configured to interpret data received from each respective device corresponding to the properties described in the subgraph.

22. The method as recited in claim 17, wherein each respective input interface is connected to a respective aspect processing device with which the respective aspect model is associated.

23. The method as recited in claim 22, wherein each respective processing is configured to provide a portion of those runtime data at a respective output interface which are provided to the respective input interface with which the respective aspect processing device is associated.

24. The method as recited in claim 23, wherein the portion of runtime data provided at the respective output interface is contained in an aspect of the runtime data which characterizes that respective aspect model which is associated with the respective aspect processing device to which the respective output interface belongs.

25. The method as recited in claim 23, wherein the individual data points and/or the data points of the groups of data points are those data points that are provided at the respective output interface.

26. The method as recited in claim 19, wherein the properties established by the respective subgraph, predefined in a hierarchical structure of selectable classes, are predefined by the metamodel.

27. The method as recited in claim 22, wherein each respective aspect processing device is created from the respective aspect models.

28. A non-transitory machine-readable memory medium on which is stored a computer program for generating a data integration device, including respective input interfaces to each of which a respective device which delivers respective runtime data to the respective input interface is connectable, the respective runtime data of each of the respective devices being characterized using at least one respective aspect model that is associated with the respective input interface and that characterizes an aspect of the respective runtime data, the computer program, when executed by a computer, causes the computer to perform the following steps:
providing, from a metamodel, to each respective input interface associated with the respective aspect model, respective rules that are defined by the metamodel; and
setting up each respective aspect model according to the respective rules.

29. A computer configured to generate a data integration device, including respective input interfaces to each of which a respective device which delivers respective runtime data to the respective input interface is connectable, the respective runtime data of each of the respective devices being characterized using at least one respective aspect model that is associated with the respective input interface and that characterizes an aspect of the respective runtime data, the computer configured to:
provide, from a metamodel, to each respective input interface associated with the respective aspect model, respective rules that are defined by the metamodel; and
set up each respective aspect model according to the respective rules.
